(19) United States
(12) Patent Application Publication
(10) Pub. No.: US 2026/0013295 A1
(43) Pub. Date: Jan. 8, 2026

(54) Stretchable Display Panel and Method for Manufacturing the Same, and Display Apparatus

(71) Applicant: BOE TECHNOLOGY GROUP CO., LTD., Chaoyang District, Beijing (CN)

(72) Inventors: Zhongyuan Sun, Beijing (CN); Jinxiang Xue, Beijing (CN); Wenqi Liu, Beijing (CN); Che An, Beijing (CN); Weijie Wang, Beijing (CN); Fengjie Zhang, Beijing (CN); Keyi Zhang, Beijing (CN); Zhiqiang Jiao, Beijing (CN); Guangcai Yuan, Beijing (CN); Jinglu Bai, Beijing (CN); Fang Liu, Beijing (CN)

(21) Appl. No.: 18/728,248

(22) PCT Filed: May 26, 2023
(86) PCT No.: PCT/CN2023/096680

§ 371 Date: Jul. 11, 2024

(51) Int. Cl. H10H 29/49; H10H 29/01

(52) U.S. Cl. CPC H10H 29/49; H10H 29/012

(57) ABSTRACT

A stretchable display panel includes an island area and a bridge area that are connected. The island area includes a display structure. The stretchable display panel further includes a first support layer and a first connection line. The first support layer includes a first surface located in the bridge area. The first connection line is connected to the display structure. The first connection line passes through the first surface, a portion of the first connection line located on the first surface includes extensible portion(s), and an extensible portion is arranged obliquely relative to a display surface of the stretchable display panel.

### CROSS-REFERENCE TO RELATED APPLICATION

This application is the United States national phase of International Patent Application No. PCT/CN2023/096680, filed May 26, 2023, the disclosure of which is hereby incorporated by reference in its entirety.

### BACKGROUND OF THE INVENTION

### Field of the Invention

The present disclosure relates to the field of display technologies, and in particular, to a stretchable display panel and a method for manufacturing the same, and a display apparatus.

### Description of Related Art

Both sub-millimeter light-emitting diodes (mini light-emitting diodes, mini LEDs) and micro light-emitting diodes (micro LEDs) have characteristics of high luminous efficiency, long life, low power consumption and fast response. A self-luminous display composed of mini LEDs or micro LEDs as pixels in a display panel may achieve a higher pixel density compared with small pitch LED displays, and thus a display apparatus (such as a mobile phone) including the mini LEDs or the micro LEDs will have better contrast and a high dynamic range lighting rendering display effect.

### SUMMARY OF THE INVENTION

In an aspect, a stretchable display panel is provided. The stretchable display panel has an island area and a bridge area that are connected. The stretchable display panel includes a display structure located in the island area, a first support layer and a first connection line. The first support layer includes a first surface located in the bridge area. The first connection line is connected to the display structure. The first connection line passes through the first surface, a portion of the first connection line located on the first surface includes at least one extensible portion, and an extensible portion is disposed obliquely relative to a display surface of the stretchable display panel.

In some embodiments, the first support layer is of a flexible structure. The first surface includes a first planarization portion and a first deformation portion, the first planarization portion is parallel to the display surface, the first deformation portion is convex or concave relative to the first planarization portion in a first direction, and the first direction is perpendicular to the display surface. The first connection line passes through the first planarization portion and the first deformation portion, and the extensible portion covers the first deformation portion.

In some embodiments, the first support layer includes a first flexible layer and a first flexible portion. The first flexible portion is located on a surface of the first flexible layer proximate to the display surface of the stretchable display panel, and the first deformation portion includes at least part of a surface of the first flexible portion proximate to the display surface.

In some embodiments, a shape of a cross section of the first flexible portion includes any one of a trapezoid, an arch, and a rectangle, and the cross section is a surface taken along the first direction and parallel to an extension direction of the first connection line.

In some embodiments, the first support layer further includes a second flexible portion. The second flexible portion is located on a surface of the first flexible portion facing away from the first flexible layer, and an orthographic projection of the second flexible portion on the first flexible layer is located within an orthographic projection of the first flexible portion on the first flexible layer. The first deformation portion includes a surface of an entirety of the first flexible portion and the second flexible portion proximate to the display surface.

In some embodiments, a shape of a cross section of the second flexible portion includes any one of a trapezoid, an arch, and a rectangle, and the cross section is a surface taken along the first direction and parallel to the extension direction of the first connection line.

In some embodiments, the first support layer has a single-layer structure and includes a first flexible layer. A surface of the first flexible layer proximate to the display surface of the stretchable display panel includes a first recessed portion, and the first deformation portion is the first recessed portion.

In some embodiments, a shape of a cross section of the first recessed portion includes one of a trapezoid, an arch and a rectangle, and the cross section is a surface taken along the first direction and parallel to an extension direction of the first connection line.

In some embodiments, the stretchable display panel further includes at least one first organic planarization layer and at least one second connection line. The first organic planarization layer and the first support layer are stacked. A portion of the first organic planarization layer located in the bridge area is a second support layer. A structure of the second support layer is the same or substantially the same as a structure of the first support layer, and a structure of the second connection line is the same or substantially the same as a structure of the first connection line. The second connection line is connected to the display structure and passes through the second support layer.

In some embodiments, a dimension of the first organic planarization layer in the first direction is less than or equal to 2 nm.

In some embodiments, the first connection line and the second connection line are connected in parallel.

In some embodiments, the at least one extensible portion include a plurality of extensible portions, and the plurality of extensible portions are sequentially arranged in an extension direction of the first connection line.

In some embodiments, the at least one extensible portion includes a protrusion and/or a depression in a first direction, and the first direction is perpendicular to the display surface.

In some embodiments, a shape of a cross section of the extensible portion includes any one of a trapezoid, an arch and a rectangle, the cross section is a surface taken along a first direction and parallel to an extension direction of the first connection line, and the first direction is perpendicular to the display surface.

In some embodiments, the first support layer is located on a side of the display structure facing away from the display surface of the stretchable display panel. The first connection line is connected to a portion of the display structure proximate to the display surface. The extensible portion is located in a surface of the first connection line facing away from the first support layer.

In some embodiments, the stretchable display panel further includes a conductive pattern layer, and a material of the conductive pattern layer is the same as a material of the first connection line.

In another aspect, a method for manufacturing a stretchable display panel is provided. The stretchable display panel includes an island area and a bridge area that are connected. The method includes: forming a display structure in the island area; and forming a first support layer and a first connection line. The first support layer includes a first surface located in the bridge area. The first connection line is connected to the display structure. The first connection line passes through the first surface, a portion of the first connection line located on the first surface includes at least one extensible portion, and an extensible portion is disposed obliquely relative to a display surface of the stretchable display panel.

In some embodiments, forming the first support layer and the first connection line, includes: providing a first initial support layer; forming the first connection line on the first initial support layer; and removing part of the first initial support layer to form the first support layer.

In some embodiments, after forming the first connection line on the first initial support layer and before removing the part of the first initial support layer to form the first support layer, the method further includes: forming at least one first organic planarization layer, the first organic planarization layer and the first support layer being stacked; and forming a second connection line on a side of the first organic planarization layer away from the first support layer, the second connection line being connected to the display structure.

In yet another aspect, a display apparatus is provided. The display apparatus includes the above stretchable display panel.

### BRIEF DESCRIPTION OF THE DRAWINGS

In order to describe the technical solutions in the present disclosure more clearly, the accompanying drawings to be used in some embodiments of the present disclosure will be introduced briefly below. Obviously, the accompanying drawings in the following description are only accompanying drawings of some embodiments of the present disclosure, and those of ordinary skill in the art may obtain other drawings according to these drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance to some embodiments;

FIG. 2 is a structural diagram of a display module, in accordance to some embodiments;

FIG. 3 is a structural diagram of a stretchable display panel, in accordance to some embodiments;

FIG. 4 is a cross-sectional view taken along a line A-A in FIG. 3;

FIGS. 5 to 7 are each a cross-sectional view taken along a line B-B in FIG. 3;

FIG. 8 is a structural diagram of a first flexible portion before being stretched, in accordance to some embodiments;

FIG. 9 is a structural diagram of a first flexible portion after being stretched, in accordance to some embodiments;

FIGS. 10 to 14 are each a cross-sectional view taken along a line B-B in FIG. 3;

FIG. 15 is a cross-sectional view taken along a line A-A in FIG. 3;

FIGS. 16 to 18 are each a cross-sectional view taken along a line B-B in FIG. 3;

FIGS. 19 to 22 are each a structural diagram of another stretchable display panel, in accordance to some embodiments;

FIG. 23 is a structural diagram of another stretchable display panel, in accordance to some embodiments;

FIG. 24 is a cross-sectional view of FIG. 23;

FIG. 25 is a circuit diagram of a pixel circuit, in accordance to some embodiments;

FIG. 26 is a timing diagram of a pixel circuit, in accordance to some embodiments;

FIG. 27 is a flow chart of a method for manufacturing a stretchable display panel, in accordance to some embodiments;

FIGS. 28 to 33 are each a process diagram of a stretchable display panel, in accordance to some embodiments; and

FIGS. 34 to 40 are each a process diagram of another stretchable display panel, in accordance to some embodiments.

### DESCRIPTION OF THE INVENTION

The technical solutions in some embodiments of the present disclosure will be described clearly and completely with reference to the accompanying drawings. Obviously, the embodiments described are only some but not all embodiments of the present disclosure. All other embodiments obtained by those of ordinary skill in the art based on the embodiments provided by the present disclosure shall be included in the protection scope of the present disclosure.

Unless the context otherwise requires, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, the features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also indicate that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value, and the acceptable range of deviation is determined, for example, by those of ordinary skill in the art in consideration of measurement in question and errors associated with measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation, and the acceptable range of deviation is determined, for example, by those of ordinary skill in the art in view of measurement in question and errors associated with measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that, when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas are enlarged for clarity. Variations in shapes relative to the accompanying drawings due to, for example, manufacturing technologies and/or tolerances may be envisaged. Therefore, the exemplary embodiments should not be construed to be limited to the shapes of areas shown herein, but to include deviations in the shapes due to, for example, manufacturing. For example, an etched area shown in a rectangular shape generally has a feature of being curved. Therefore, the areas shown in the accompanying drawings are schematic in nature, and their shapes are not intended to show actual shapes of the areas in an apparatus, and are not intended to limit the scope of the exemplary embodiments.

Some embodiments of the present disclosure provide a display apparatus, and the display apparatus is a product having a function of displaying images (including images in stationary or images in motion, where the images in motion may be a video). The display apparatus may be, for example, a virtual reality (VR) display apparatus or an augmented reality (AR) display apparatus. The display apparatus may be, for example, a monitor, a mobile phone, a tablet computer (pad), a notebook computer, a television, a personal digital assistant (PDA), an ultra-mobile personal computer (UMPC), a netbook, a wearable device (such as a smart watch) or a vehicle-mounted display apparatus. The type of the display apparatus is not limited in the present embodiments.

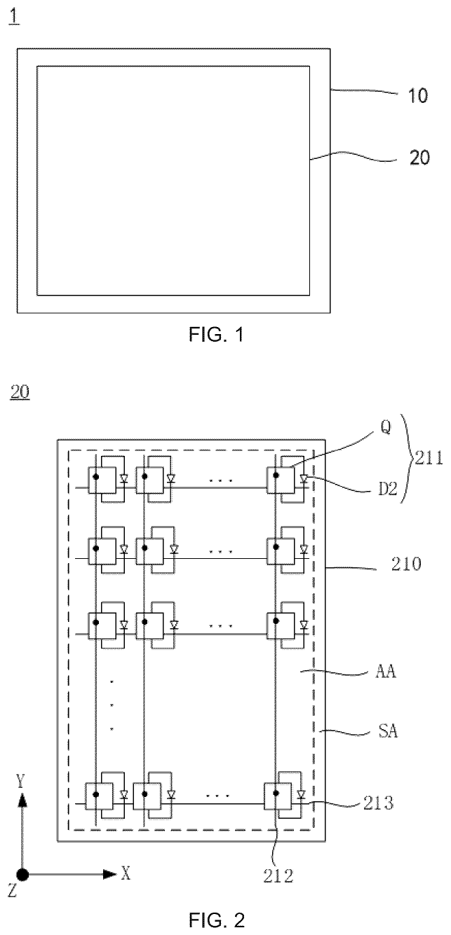

Referring to FIG. 1, the display apparatus 1 includes a display module 20, and may further include a controller, a frame 10 (such as a middle frame), and the like. The controller, such as a central processing unit (CPU) or a graphics processing unit (GPU), is configured to send image data (e.g., grayscale data) to the display module 20. The display module 20 is a component configured to display a picture. For example, the display module 20 is configured to receive image data and display a picture corresponding to the image data. The frame 10 is configured to fix the display module 20, the controller, and the like.

Referring to FIG. 2, the display module 20 may include a stretchable display panel 210. The stretchable display panel 210 is configured to receive a data signal (e.g., a voltage signal) corresponding to the image data, and display an image (i.e., a picture) based on the data signal. The stretchable display panel 210 may have a display area AA and a non-display area SA. The display area AA of the stretchable display panel 210 is an area of the stretchable display panel 210 capable of displaying images. An area of the stretchable display panel 210 other than the display area AA is the non-display area SA. The non-display area SA may be located on at least one side (e.g., one side or multiple sides) of the display area AA. For example, the non-display area SA surrounds the display area AA.

The stretchable display panel 210 includes a plurality of sub-pixels 211 located in the display area AA. The plurality of sub-pixels 211 include first sub-pixels used for emitting light of a first color, second sub-pixels used for emitting light of a second color, and third sub-pixels used for emitting light of a third color. The first color, the second color, and the third color are three primary colors (e.g., red, green and blue). For example, the stretchable display panel 210 may include red sub-pixels, green sub-pixels and blue sub-pixels.

The stretchable display panel 210 further includes a plurality of signal lines, such as a plurality of gate lines 213 and a plurality of data lines 212. Each sub-pixel 211 may be coupled to a gate line 213 and a data line 212, and is configured to write a data signal transmitted by the data line 212 in response to a scanning signal transmitted by the gate line 213, and emit light with corresponding intensity based on the data signal.

The plurality of gate lines 213 may extend approximately in a third direction X. For example, a gate line 213 may be parallel to the third direction X. As another example, there is a relatively small included angle between an extending direction of a gate line 213 and the third direction. For example, the relatively small included angle is in a range from −8° to 8°, inclusive; alternatively, the relatively small included angle is in a range from −5° to 5°, inclusive. In the following, the relatively small included angle described may refer to the value range of the included angle, and adaptive selection may be made within the value range. A (e.g., each) gate line 213 may be coupled to sub-pixels 211 of a same row and configured to transmit a scanning signal to the sub-pixels 211 of the row. For example, the gate lines 213 are located in the display area AA, and may also extend into the non-display area SA.

In some examples, the stretchable display panel 210 may further include gate driver circuit(s) located in the non-display area. In this case, the gate driver circuit may be called a gate on array (GOA) circuit. The gate driver circuit is coupled to the plurality of gate lines 213, and configured to provide scanning signals to the gate lines 213. For example, the gate driver circuit may be disposed on a side (e.g., left side or right side) of the display area in the third direction. In some other examples, the gate driver circuit may be a gate driver chip that is not included in the stretchable display panel 210 but is coupled to the plurality of gate lines 213 in the stretchable display panel 210.

The plurality of data lines 212 may extend approximately in a second direction Y. The second direction Y is perpendicular to the third direction X. For example, a data line 212 may be parallel to the second direction Y. As another example, there is a relatively small included angle between a data line 212 and the second direction. A (e.g., each) data line 212 may be coupled to sub-pixels 211 of a same column and configured to provide a data signal to the sub-pixels 211 of the column. For example, the data lines 212 are located in the display area AA, and may also extend into the non-display area SA.

For example, the display module 20 may further include a driver chip, which may specifically be a driver integrated circuit (IC), such as a source driver IC or a display driver integrated circuit (DDIC). The driver chip is coupled to the stretchable display panel 210 and may, for example, be bonded to the non-display area SA of the stretchable display panel 210. The driver chip is configured to provide corresponding data signals to the stretchable display panel 210 based on the received image data. In some examples, the driver chip is coupled to the plurality of data lines 212 and configured to provide data signals to the data lines 212. For example, the stretchable display panel 210 further includes a plurality of fan-out lines located in the non-display area, and an area where the fan-out lines are located may be called a fan-out area. The driver chip is coupled to the plurality of data lines 212 by the plurality of fan-out lines in the fan-out area. Each data line 212 is coupled to a fan-out line, an end of the fan-out line extends to a boundary of the display area, and the other end the fan-out line extends to the location where the driver chip is located.

In addition, the display module 20 may further include a circuit board, such as a flexible circuit board. For example, the circuit board may be bonded to the non-display area SA of the stretchable display panel 210, coupled to the driver chip, and configured to transmit the image data output by the controller to the driver chip, so that the driver chip generates corresponding data signals based on the image data.

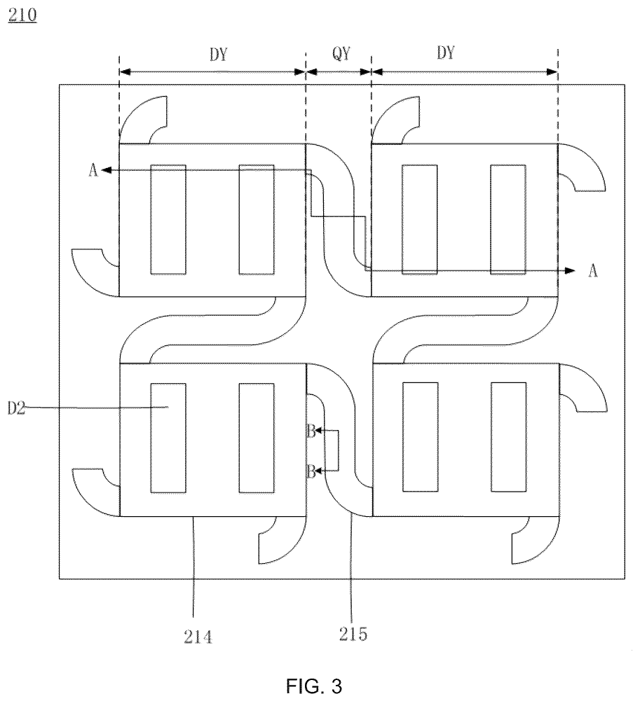

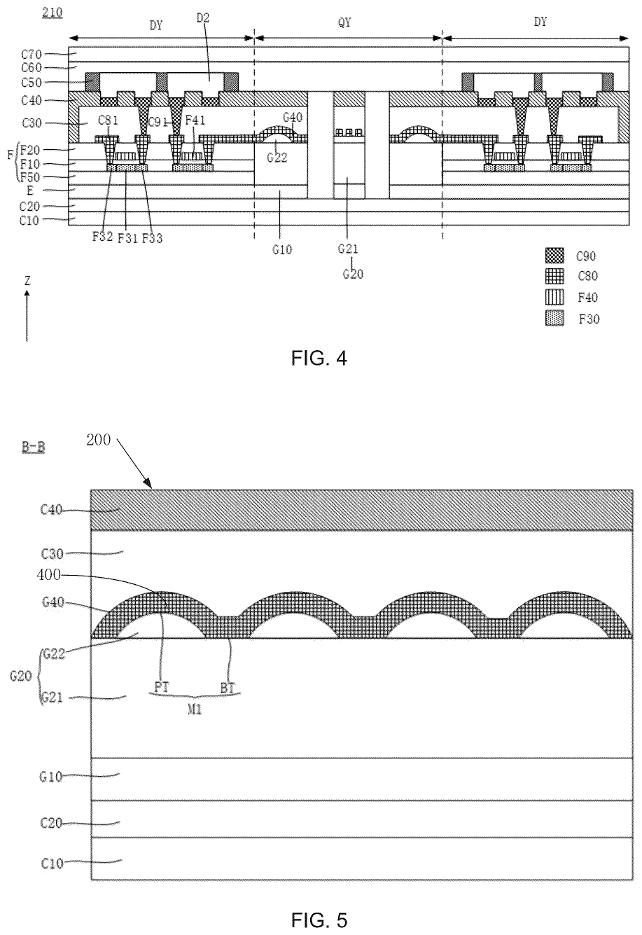

Referring to FIGS. 3 and 4, the stretchable display panel 210 includes island areas DY and bridge areas QY that are connected. In some examples, both the island areas DY and the bridge areas QY are located in the above display area.

For example, the stretchable display panel 210 further includes a display structure 214 located in the island area DY and a connection structure 215 located in the bridge area QY, and the connection structure 215 is configured to be connected to an adjacent display structure 214.

In some examples, the display structure 214 includes a second substrate E and a circuit layer F that are stacked.

The structure of the second substrate E may be selected according to actual needs. For example, the second substrate E may be a rigid substrate. The rigid substrate may include, for example, a glass substrate, a quartz substrate, or a plastic substrate. As another example, the second substrate E may be a flexible substrate. The flexible substrate may include, for example, a polyimide substrate, a polymethyl methacrylate substrate, or a polyethylene naphthalate substrate.

The circuit layer F includes a buffer layer F50 and an active pattern layer F30 that are stacked. The buffer layer F50 is disposed on a side of the second substrate E; and the active pattern layer F30 is disposed on a side of the buffer layer F50 away from the second substrate E. The active pattern layer F30 includes a plurality of active patterns F31. The active pattern layer F30 has an active area, and a first electrode area F32 and a second electrode area F33 that are located on two opposite sides of the active area. A portion of the active pattern layer F30 located in the active area may be called an active pattern F31. One of the first electrode area F32 and the second electrode area F33 is a source area (which may be used as a source), and the other thereof is a drain area (which may be used as a drain). The materials of the two may be doped polysilicon to present a property of being capable of conducting electricity. In addition, the circuit layer F further includes a first insulating layer F10, a gate pattern layer F40, and a second insulating layer F20 that are sequentially stacked on the active pattern layer F30. The gate pattern layer F40 may include a plurality of gates F41. In some examples, a gate F41 in the gate pattern layer F40 and an active pattern F31 in the active pattern layer F30 (or the active area, the first electrode area F32 and the second electrode area F33) may constitute a transistor. The gate pattern layer F40 may be made of a metallic material, such as at least one of aluminum (Al), silver (Ag), copper (Cu), chromium (Cr), titanium (Ti), or molybdenum (Mo).

For example, the stretchable display panel 210 further includes a first optical adhesive layer C20 and a first flexible protective film C10. The first flexible protective film C10 is pasted on the second substrate E of the display structure 214 by the first optical adhesive layer C20. The material of the first flexible protective film C10 may be a material having elasticity (which may be called an elastic material). For example, the elastic material may be polydimethylsiloxane (PDMS), styrene ethylene butylene styrene (SEBS), aliphatic aromatic random copolyester (Ecoflex), or rubber.

For example, the stretchable display panel 210 further includes a conductive pattern layer C80, and the conductive pattern layer C80 is disposed on the circuit layer F (or the second insulating layer F20) of the display structure 214. The conductive pattern layer C80 includes a plurality of first connection portions C81 located in the island area DY. At least one (e.g., one or more) first connection portion C81 is coupled to an active pattern F31. In some examples, there may be two first connection portions C81 coupled to an active pattern F31, one of the first connection portions C81 is coupled to the first electrode area F32 located on a side of the active pattern F31, and the other of the first connection portions C81 is coupled to the second electrode area F33 located on another side of the active pattern F31.

In the embodiments of the present disclosure, the term “pattern layer” may be at least one film layer is formed by using a same film-forming process, and then a patterning process is performed on the at least one film layer to form a layer structure including specific pattern. Depending on different specific patterns, the patterning process may include several applying adhesive, exposure, development or etching processes. The specific patterns in the formed layer structure may be continuous or discontinuous, and these specific patterns may also be at different heights (or have different thicknesses).

The stretchable display panel 210 further includes a first support layer G20 and a first connection line G40. The material of the first connection line G40 may be a metal. The metal may be a single substance, such as titanium, aluminum, molybdenum, copper, silver, or gold; alternatively, the metal may be an alloy, such as alloys of the above single substances (e.g., titanium-aluminum alloy, or aluminum-neodymium alloy). The material of the first connection line G40 may also be a non-metallic material with the tensile property and the conductive property. The non-metallic material may be nano silver wires, carbon nanotubes, or graphene, alternatively, the non-metallic material may be mixtures of carbon nanotubes, silver nanosheets, stretchable resin, and rubber.

The first support layer G20 includes a first surface M1 located in the bridge area QY. The first connection line G40 passes through the first surface M1. For example, the first connection line G40 extends from an island area DY to another island area DY through the first surface M1. The first connection line G40 is connected to the display structure 214. For example, the first connection line G40 may be connected to a first connection portion C81 in the display structure 214. In this way, when the stretchable display panel 210 is stretched, a distance between adjacent display structures 214 increases, so that the first connection line G40 is stretched within a display surface, thereby increasing the size of the stretchable display panel 210. However, since the first connection line G40 is stretched within the display surface, the elongation amount (the elongation amount may be understood as a difference between a distance before stretching and a distance after stretching) of the first connection line G40 is limited, thereby making the tensile property of the stretchable display panel 210 poor. The display surface may be a surface of the stretchable display panel 210 for displaying images.

In order to solve the problem of poor tensile property of the stretchable display panel 210, in embodiments of the present disclosure, a portion of the first connection line G40 located on the first surface M1 includes extensible portion(s) 400. The extensible portion is provided obliquely relative to the display surface 200 of the stretchable display panel 210, which may be understood as that the extensible portion has deformation in a direction perpendicular to the display surface. In this way, the extensible portion may increase the elongation amount of the first connection line G40, so that the elongation amount of the connection structure 215 may increase, thereby increasing the stretchable distance between adjacent display structures 214 and further improving the tensile property of the stretchable display panel 210.

For example, the extensible portion has a protrusion shown in FIG. 4 in the first direction Z. When stretching, the height of the protrusion decreases, so that a size of an orthographic projection of the protrusion on the display surface increases, thereby increasing the elongation amount of the extensible portion. As another example, the extensible portion has a depression in the first direction Z. When stretching, the depth of the depression decreases, so that a size of an orthographic projection of the depression on the display surface increases, thereby increasing the elongation amount of the extensible portion. As yet another example, the extensible portion has a protrusion and a depression in the first direction Z, and the height of the protrusion and the depth of the depression both decrease, thereby increasing the elongation amount of the extensible portion. The first direction Z is perpendicular to the display surface. In the examples, the extensible portion may be understood as the above protrusions and/or depressions.

For example, the first connection line G40 has a plurality of extensible portions, and the plurality of extensible portions are arranged in sequence in the extension direction of the first connection line G40. The number of the extensible portions may increase the elongation amount of the first connection line G40. For example, the cross-sectional shape of the extensible portion includes any of a trapezoid, an arch, and a rectangle. The cross section is a surface taken along the first direction Z and parallel to the extension direction of the first connection line G40.

In some embodiments, the stretchable display panel 210 further includes a third insulating layer C30, a lead layer C90, a light-emitting device D2, a barrier adhesive C50, a second optical adhesive layer C60, and a second flexible protective film C70.

The third insulating layer C30 is disposed on the second insulating layer F20, and the third insulating layer C30 covers the conductive pattern layer C80. The material of the third insulating layer C30 is an organic material such as polyimide.

The lead layer C90 is disposed on a side of the third insulating layer C30 away from the second insulating layer F20. The material of the lead layer C90 is a metal such as copper. The lead layer C90 includes a plurality of guide portions C91, and the guide portions C91 are connected to the first connection portions C81 of the conductive pattern layer C80 through first through holes in the third insulating layer C30. The guide portion C91 may be deposited in the first through hole in the third insulating layer C30 by an electroforming process.

At least one (e.g., one or more) light-emitting device D2 is located in an island area DY. In some examples, there may be three light-emitting devices D2 in an island area DY, and the three light-emitting devices D2 may be light-emitting devices D2 for emitting light of three colors. For example, the light-emitting devices D2 for emitting light of three colors may be red, blue, and green light-emitting devices D2. The light-emitting device D2 is a device that can emit light after being energized. For example, the light-emitting device D2 may be a light-emitting diode (LED), a tiny LED, or a quantum dot light-emitting diode (QLED), which is not limited here. As an example, the light-emitting device D2 may be a tiny light-emitting device, and the size of the tiny light-emitting device may refer to the size of the tiny LED. The tiny LED includes a sub-millimeter or even micron-sized light-emitting diode, or may include a smaller-sized light-emitting diode. The sub-millimeter light-emitting diode is also called a mini light-emitting diode (mini LED). The size (such as length) of the mini LED may be in a range of 50 microns to 150 microns, inclusive, such as in a range of 80 microns to 120 microns, or 100 microns or below. The micron-sized light-emitting diode is also called a micro light-emitting diode (micro LED). For example, the size (such as length) of the micro LED may be less than 50 microns, such as in a range of 10 microns to 50 microns. The light-emitting device D2 may include at least one (e.g., one or more) pin coupled to the active pattern F31. For example, a pin may be coupled to a guide portion C91, and coupled to an active pattern F31 by a guide portion C91 and a first connection portion C81 that are connected.

The barrier adhesive C50 is provided at a periphery of the light-emitting device D2. For example, the barrier adhesive C50 may be formed at a periphery of the light-emitting device D2 in the island area DY by printing or inkjet printing. The barrier adhesive C50 may be an opaque adhesive material to prevent color crosstalk of light emission between adjacent light-emitting devices D2.

The second flexible protective film C70 is pasted on a surface of the light-emitting device D2 away from the third insulating layer C30 by the second optical adhesive layer C60. The second optical adhesive layer C60 may be optical clear adhesive. The material of the second flexible protective film C70 may be a material having elasticity (which may be called an elastic material). For example, the elastic material may be polydimethylsiloxane (PDMS), styrene ethylene butylene styrene (SEBS), aliphatic aromatic random copolyester (Ecoflex), or rubber.

The first support layer G20 represents different meanings in different examples. Two examples will be provided below to illustrate the first support layer G20.

### EXAMPLE ONE

Referring to FIGS. 3 to 5, the first support layer G20 may be disposed on a first substrate G10 of the connection structure 215. In this case, the first connection line G40 and the first connection portion C81 may be formed by a single patterning process, that is, the first connection line G40 also belongs to the conductive pattern layer C80. In a case where the first support layer G20 is disposed on the first substrate G10 of the connection structure 215, the material of the conductive pattern layer C80 is the same as the material of the first connection line G40. In a case where the materials of the conductive pattern layer C80 and the first connection line G40 are non-metal, patterning may be achieved by inkjet printing, 3D printing, printing, nanoimprinting, or other processes. In some examples, the second insulating layer F20 is flush with the first support layer G20, so that the first connection line G40 may be prevented from breaking at an interface between the second insulating layer F20 and the first support layer G20.

In some examples, the connection structure 215 includes a first substrate G10, and the material of the first substrate G10 is a flexible material. For example, the flexible material may include a polyimide substrate, a polymethyl methacrylate substrate, or a polyethylene naphthalate substrate. In a possible implementation, in a case where the second substrate E is a flexible substrate, the first substrate G10 and the second substrate E may be substrates of the same materials, such as the polyimide substrates. In this case, the first substrate G10 and the second substrate E may be formed by a single patterning process. In this case, the first flexible protective film C10 is also pasted on the first substrate G10 of the connection structure 215 by the first optical adhesive layer C20.

In some embodiments, the first support layer G20 is of a flexible structure. The material of the first support layer G20 may be an organic material.

The first surface M1 includes first planarization portions BT and first deformation portions PT. For example, in a target area, the first surface M1 includes the first planarization portion BT and the first deformation portion PT connected to each other. The target area may include the bridge area QY, or the target area may include the bridge area QY and an area of the island area DY proximate to the bridge area QY.

The first planarization portion BT is parallel to the display surface, and the first deformation portion PT is convex or concave (e.g., convex, or concave, or convex and concave) relative to the first planarization portion BT in the first direction Z.

The first connection line G40 passes through the first planarization portions BT and the first deformation portions PT. The extensible portion covers the first deformation portion PT, which may be understood as that the shape of the extensible portion is the same as the shape of the first deformation portion PT. That is, at the first deformation portion PT, the extensible portion may be convex and/or concave relative to the first planarization portion BT; that is to say, the extensible portion has a protrusion and/or a depression in the first direction Z.

For example, the first support layer G20 may be of a multi-layer structure. The first support layer G20 includes a first flexible layer G21 and at least one (e.g., one or more) first flexible portion G22. The first flexible portion G22 may be made of a material with the tensile property and the resilience property, such as epoxy resin, acrylic resin, or silicone resin. The first substrate G10 and the first flexible layer G21 are stacked.

The first flexible portion G22 is located on a surface of the first flexible layer G21 proximate to the display surface of the stretchable display panel 210. For example, the first flexible portion G22 is disposed on a surface of the first flexible layer G21 away from the first substrate G10.

A surface of the first flexible portion G22 proximate to the display surface is the first deformation portion PT. The first planarization portion BT may be a portion of a surface of the first flexible layer G21 away from the first substrate G10, and the portion does not overlap with the first flexible portion G22.

Any two adjacent first deformation portions PT have equal distance therebetween. For example, any two adjacent first flexible portions G22 have equal distance therebetween. In this way, it facilitates calculation of the elongation amount of the first connection line G40. The value of the distance may be in a range from 0 μm to 100 μm, inclusive (e.g., 0 μm, 10 μm, 20 μm, 30 um, 40 μm, 50 μm, 60 μm, 70 μm, 80 μm, 90 μm, or 100 μm).

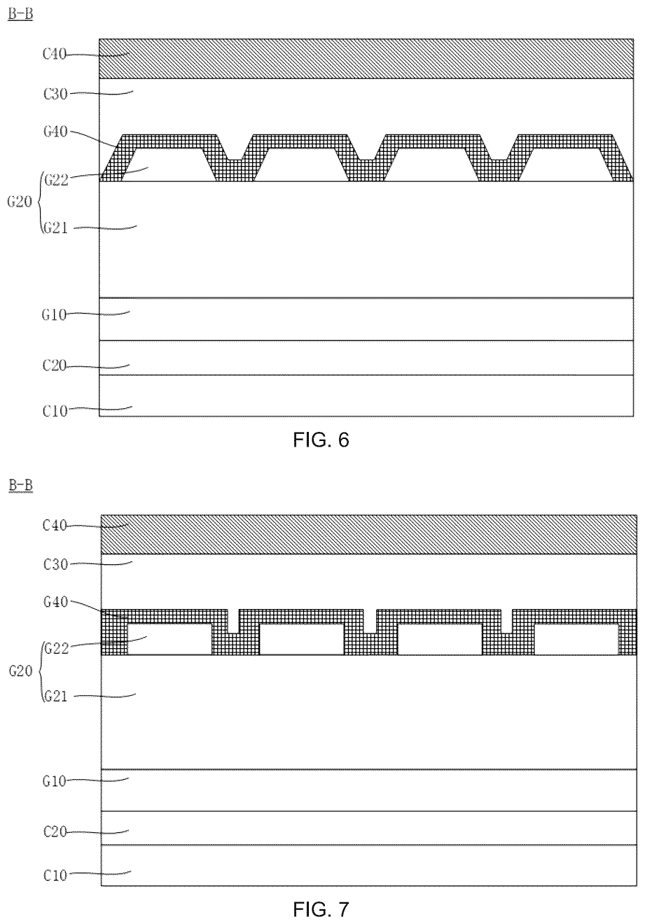

The cross-sectional shape of the first flexible portion G22 includes any of a trapezoid, an arch, and a rectangle, and the cross section is a surface taken along the first direction Z and parallel to the extension direction of the first connection line G40 (e.g., the cross section may be a section taken along the B-B section line shown in FIG. 3; and the cross section appearing below may also be the section taken along the B-B section line shown in FIG. 3). For example, the cross section of the first flexible portion G22 shown in FIG. 5 is arched. For example, the cross section of the first flexible portion G22 shown in FIG. 6 is trapezoidal. For example, the cross section of the first flexible portion G22 shown in FIG. 7 is rectangular.

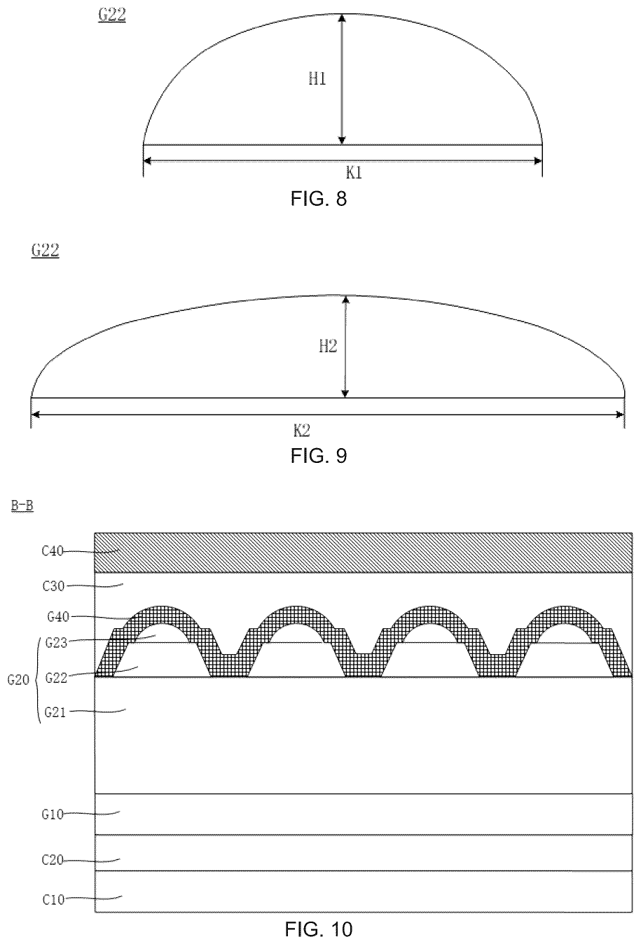

The following describes changes of the first flexible portion G22 before and after stretching in a case where the cross section of the first flexible portion G22 is arched. Referring to FIGS. 8 and 9, in a case where the first flexible portion G22 is arched, a width K1 of the first flexible portion G22 may be in a range from 3 μm to 100 μm, inclusive (e.g., 3 μm, 5 μm, 8 μm, 10 μm, 20 μm, 30 μm, 40 μm, 50 μm, 60 μm, 70 μm, 80 μm, 90 μm, or 100 μm), and a height H1 of the first flexible portion G22 may be in a range from 1.5 μm to 32 μm, inclusive (e.g., 1.5 μm, 2 μm, 3 μm, 5 μm, 10 μm, 15 μm, 20 μm, 25 μm, 30 μm, or 32 μm). When the first flexible portion G22 is not stretched, the width of the first flexible portion G22 is K1, and the height of the first flexible portion G22 is H1. When the first flexible portion G22 is stretched, the width of the first flexible portion G22 is K2, and the height of the first flexible portion G22 is H2. K2 is greater than K1, and H1 greater than H2. The relationship between the width K1 of the first flexible portion G22 and the height H1 of the first flexible portion G22 satisfies the following formulas: L1=πH1+4(0.5K1−H1), and S1=0.5πH1K1. The relationship between the width K2 of the first flexible portion G22 and the height H2 of the first flexible portion G22 satisfies the following formulas: L2=πH2+4(0.5K2−H2), and S2=0.5πH2K2. Since an area of the first flexible portion G22 remains unchanged before and after stretching, that is, S1 is equal to S2, it can be obtained that H1K1=H2K2. In a case of H1=3 um and K1=8 um, if L1=13.42 um, H1K1=H2K2=24 um. According to H2K2=24 um, when the stretchable display panel 210 is stretched along the extension direction of the width of the first flexible portion G22, it can be obtained that H2=2 um and K2=12 um, so as to obtain L2=22.28 um. Therefore, in a case of H2/H1=0.66 and K2/K1=1.5, L2/L1=1.66.

Since the first connection line G40 is disposed on an outer surface of the first flexible portion G22, a circumference of the first flexible portion G22 may be the length of the extensible portion, and the design of the first flexible portion being arched may enhance the stretch resistance ability of the first connection line G40.

Referring to FIG. 10, the first support layer G20 further includes a second flexible portion G23. The second flexible portion G23 is located on a surface of the first flexible portion G22 facing away from the first flexible layer G21, that is, the first flexible portion G22 and the second flexible portion are stacked. An orthographic projection of the second flexible portion G23 on the first flexible layer G21 is located within an orthographic projection of the first flexible portion G22 on the first flexible layer G21.

The first deformation portion PT is replaced by a surface of an entirety of the first flexible portion G22 and the second flexible portion G23 proximate to the display surface.

The cross-sectional shape of the second flexible portion G23 includes any of a trapezoid, an arch, and a rectangle. For example, in a case where the cross section of the first flexible portion G22 shown in FIG. 10 is trapezoidal, the cross section of the second flexible portion is arched. As another example, in a case where the cross section of the first flexible portion G22 shown in FIG. 11 is trapezoidal, the cross section of the second flexible portion is trapezoidal.

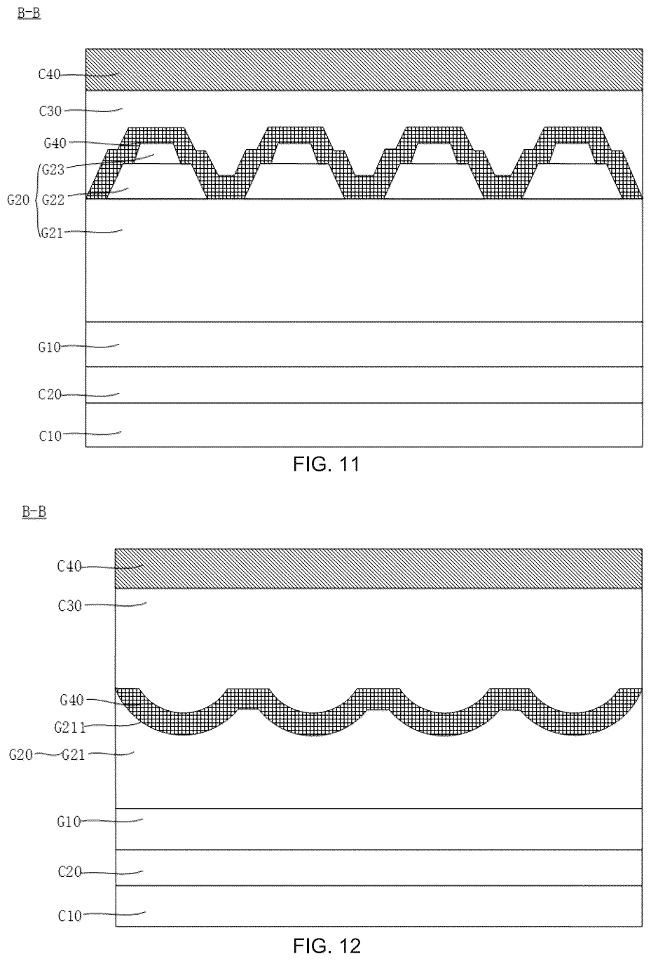

As another example, referring to FIG. 12, the first support layer G20 may have a single-layer structure. In this case, the first support layer G20 is equivalent to the above first flexible layer G21. That is, a surface of the first flexible layer G21 away from the first substrate G10 has a plurality of first recessed portions G211, and the first recessed portion G211 is the first deformation portion PT. The first planarization portion BT may be a portion of a surface of the first flexible layer G21 away from the first substrate G10, and the portion does not overlap with the plurality of first recessed portions G211.

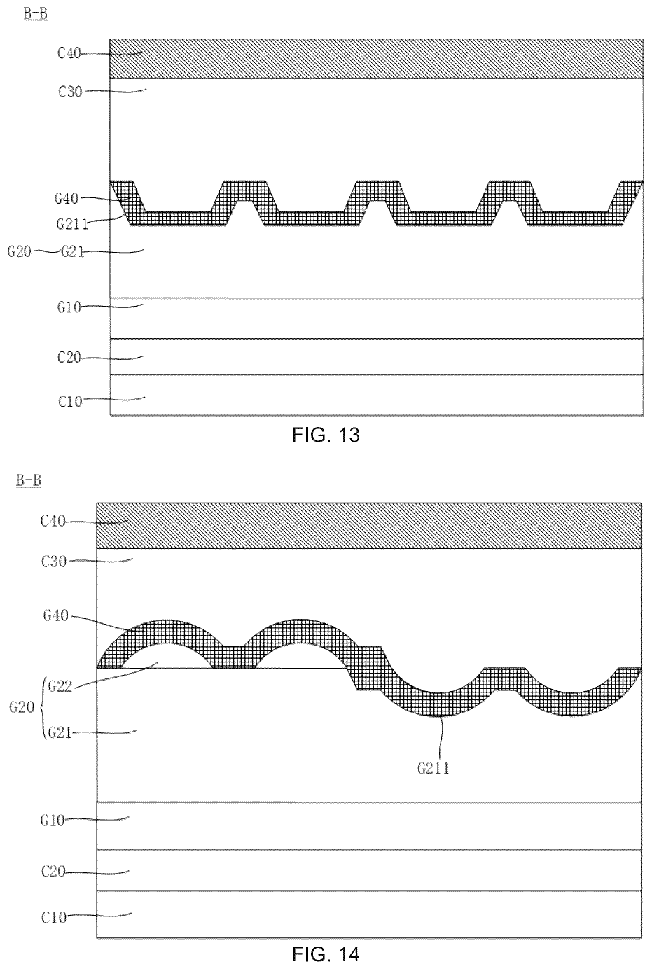

Any two adjacent first recessed portions G211 have equal distance therebetween. The value of the distance may be in a range from 0 um to 100 um, inclusive (e.g., 0 um, 10 um, 20 um, 30 um, 40 um, 50 um, 60 um, 70 um, 80 um, 90 um, or 100 um). The cross section of the first recessed portion G211 includes one of a trapezoid, an arch, and a rectangle. For example, the cross section of the first recessed portion G211 shown in FIG. 12 includes an arch. As another example, the cross section of the first recessed portion G211 shown in FIG. 13 includes a trapezoid.

As another example, referring to FIG. 14, the first support layer G20 includes a first flexible layer G21 and at least one first flexible portion G22. The first flexible portion G22 is located on a surface of the first flexible layer G21 proximate to the display surface of the stretchable display panel 210; and a surface of the first flexible layer G21 away from the first substrate G10 has a plurality of first recessed portions G211.

An entirety of the first recessed portions G211 and surfaces of the first flexible portions G22 proximate to the display surface is the first deformation portions PT. The first planarization portion BT may be a portion of a surface of the first flexible layer G21 away from the first substrate G10, and the portion does not overlap with the plurality of first recessed portions G211 and the first flexible portions G22.

Any two adjacent first recessed portions G211, any two adjacent first flexible portions G22, and a first recessed portion G211 and an adjacent first flexible portion G22 have equal distance therebetween. The value of the distance may be in a range from 0 um to 100 um, inclusive (e.g., 0 um, 10 um, 20 um, 30 um, 40 um, 50 um, 60 um, 70 um, 80 um, 90 um, or 100 um).

The cross section of the first flexible portion G22 may include one of a trapezoid, an arch, and a rectangle. The cross section of the first recessed portion G211 may include one of a trapezoid, an arch, and a rectangle. The cross section of the first recessed portion G211 has the same shape as the cross section of the first flexible portion G22. The same shape may be understood as the cross section of the first recessed portion G211 and the cross section of the first flexible portion G22 are of the same shape. For example, the cross section of the first recessed portion G211 shown in FIG. 14 is arched, and the cross section of the first flexible portion G22 shown in FIG. 14 is also arched. As another example, the cross section of the first recessed portion G211 is rectangular, and the cross section of the first flexible portion G22 is also rectangular.

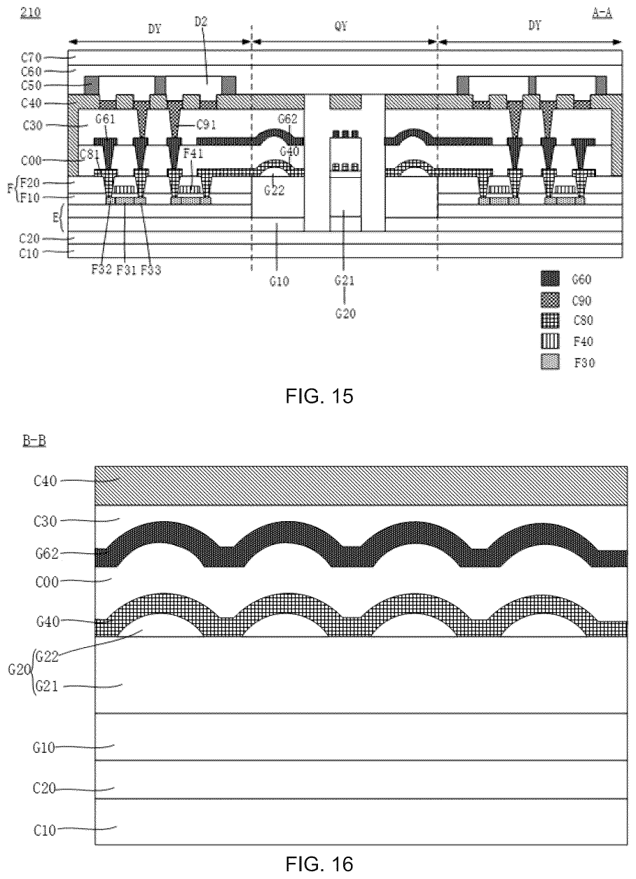

In some embodiments, referring to FIGS. 3 and 15 to 17, the stretchable display panel 210 includes at least one first organic planarization layer C00 and at least one second connection line G62. The material of the first organic planarization layer C00 is an organic material, such as polyimide. The material of the second connection line G62 may refer to the material of the first connection line G40. The first organic planarization layer C00 and the first support layer G20 are stacked, so that the first organic planarization layer C00 covers the first connection line G40. In some examples, the first organic planarization layer C00 also extends to a position between the second insulating layer F20 and the third insulating layer C30, and covers the conductive pattern layer C80. In some examples, a conductive layer G60 is formed on a side of the first organic planarization layer C00 away from the first support layer G20. The second connection line G62 and the second connection portion G61 may be formed by a single patterning process. The second connection portion G61 may be connected to the first connection portion.

The structure of the second support layer is the same or substantially the same as the structure of the first support layer G20. The second support layer is a portion of the first organic planarization layer C00 located in the bridge area QY, which can also be understood as that the second support layer is directly opposite to the first support layer G20, that is, an orthographic projection of the first support layer G20 on a plane where the display surface is located coincides with an orthographic projection of the second support layer on the plane where the display surface is located.

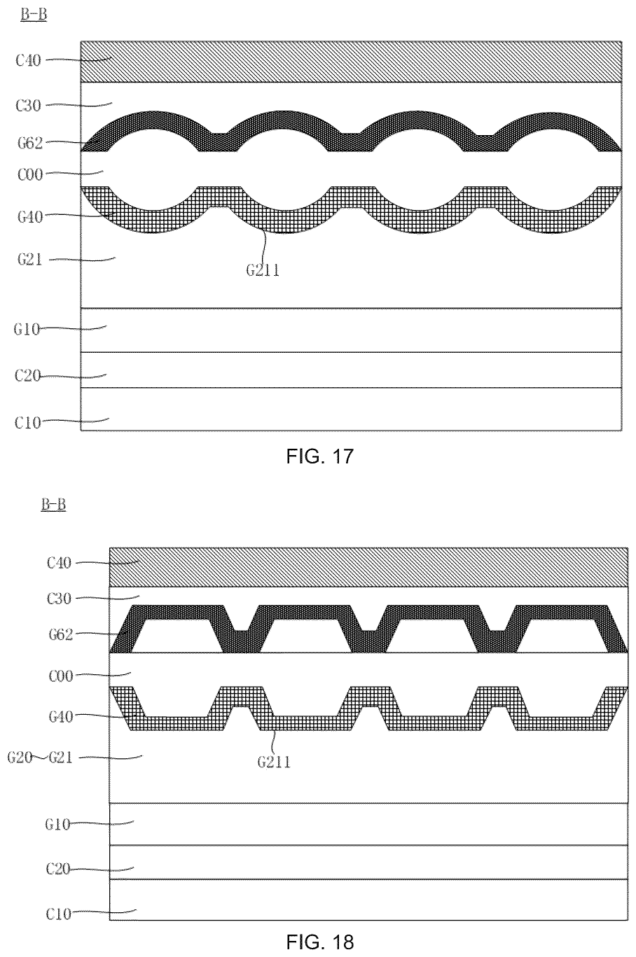

The second support layer has a second surface with the same structure as the first surface M1 of the first support layer G20; that is, the second surface includes second planarization portions and second deformation portions connected to each other. The term “same” can be understood as that the first planarization portion BT and the second planarization portion are both parallel to the display surface, and the first deformation portion PT and the second deformation portion have the same shapes and directions. For example, the first deformation portion PT and the second deformation portion are both protrusions (arches) shown in FIG. 16. As another example, the first deformation portion PT and the second deformation portion are both depressions. The term “substantially the same” (which may be called opposite) may be understood as that the first planarization portion BT and the second planarization portion are both parallel to the display surface, and the first deformation portion PT and the second deformation portion have the same shapes but opposite directions. For example, the first deformation portion PT is a depression (arch) shown in FIG. 17, and the second deformation portion PT is a protrusion (arch) shown in FIG. 17. As another example, the first deformation portion PT is a depression (trapezoid) shown in FIG. 18, and the second deformation portion is a protrusion (trapezoid) shown in FIG. 18. The second surface is a surface of the second support layer away from the first support layer G20.

In some examples, the second support layer includes a plurality of third flexible portions and/or a plurality of second recessed portions. The second deformation portions are surfaces of the plurality of third flexible portions and/or the plurality of second recessed portions away from the first support layer G20.

In some examples, a dimension of the first organic planarization layer C00 in the first direction Z is less than or equal to 2 nm (e.g., 0.1 nm, 0.3 nm, 0.5 nm, 0.7 nm, 0.8 nm, 1 nm, 1.2 nm, 1.4 nm, 1.6 nm, 1.8 nm, or 2 nm). In this way, the thickness of the first organic planarization layer C00 is relatively thin and cannot play a flattening role, so that the second deformation portions are formed in a surface of the second support layer. In addition, the dimension of the first organic planarization layer C00 is less than or equal to 2 nm, so that the thickness of the stretchable display panel 210 may be caused not to be relatively thick.

The structure of the second connection line G62 is the same or substantially the same as the structure of the first connection line G40, which may be understood as that the second connection line G62 passes through the second planarization portion and the second deformation portion, and at the second deformation portion, the second connection line G62 will be deformed correspondingly; that is, the second connection line G62 will form the same shape as the second deformation portion. As a result, the elongation amount of the second connection line G62 increases.

The second connection line G62 is connected to the display structure 214, and the second connection line G62 passes through the second surface of the second support layer. For example, the second connection line G62 extends from an island area DY to another island area DY through the second surface. In this way, the first connection line G40 and the second connection line G62 may form a dual structure, so that the first connection line G40 and the second connection line G62 have relatively small stress, thereby reducing deformation of the first connection line G40 and the second connection line G62 and further increasing the tensile property of the stretchable display panel 210.

In some examples, an end of the second connection line G62 is connected to a first connection line G40 in an island area DY, and the other end of the second connection line G62 is connected to a first connection line G40 in another island area DY. In this way, the first connection line G40 and the second connection line G62 are connected in parallel. In a case where one of the first connection line G40 and the second connection line G62 breaks, the other one may also play a conductive role, thereby reducing risk of fracture of the connection structure 215 and improving the tensile property of the stretchable display panel 210.

In some embodiments, the stretchable display panel 210 further includes a shielding layer C40. The shielding layer C40 is disposed on the third insulating layer C30. The shielding layer C40 has a plurality of second through holes, and the plurality of guide portions C91 are located in the plurality of second through holes. Thus, the plurality of guide portions C91 in the lead layer C90 may be prevented from being oxidized. In some examples, the shielding layer C40 further wraps an outer side surface of the third insulating layer C30.

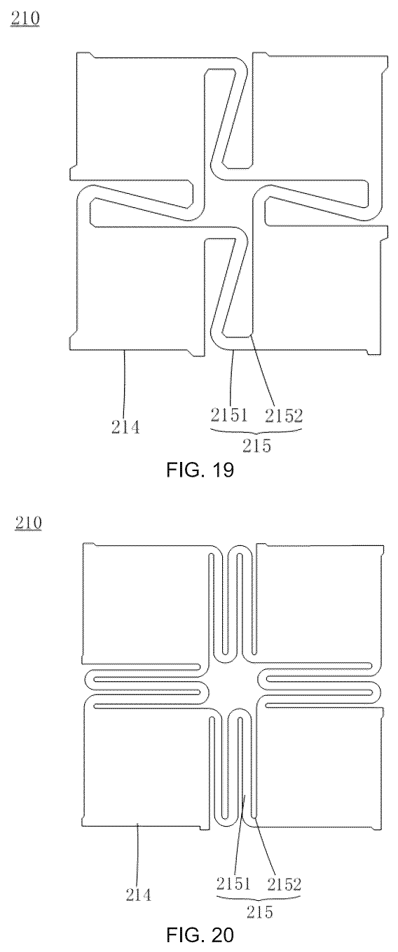

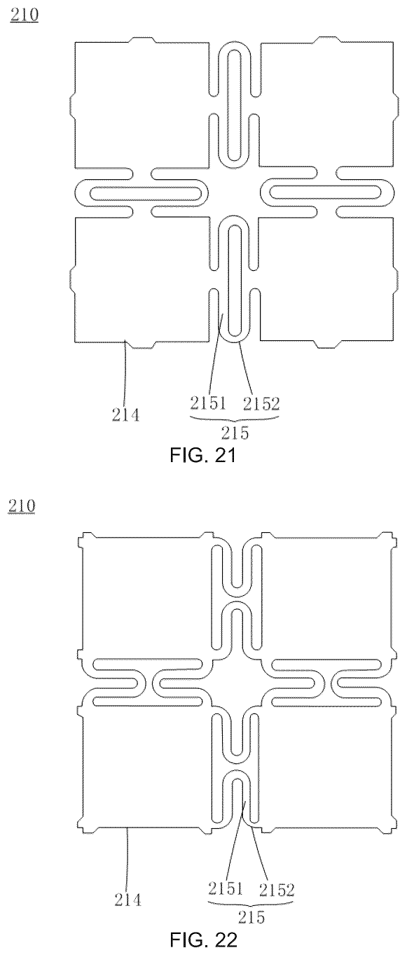

In some embodiments, referring to FIGS. 3 and 19 to 22, the connection structure 215 includes a plurality of connection segments 2151 and a plurality of arc segments 2152. The arc segments are used to connect adjacent connection segments, and connect the connection segment and the display structure 214. Since adjacent connection segments form a sharp corner when being directly connected, the stress is relatively large at the sharp corner. Thus, the arc segments are provided to reduce the stress between adjacent connection segments, thereby solving the problem of breakage due to excessive stress.

### EXAMPLE TWO

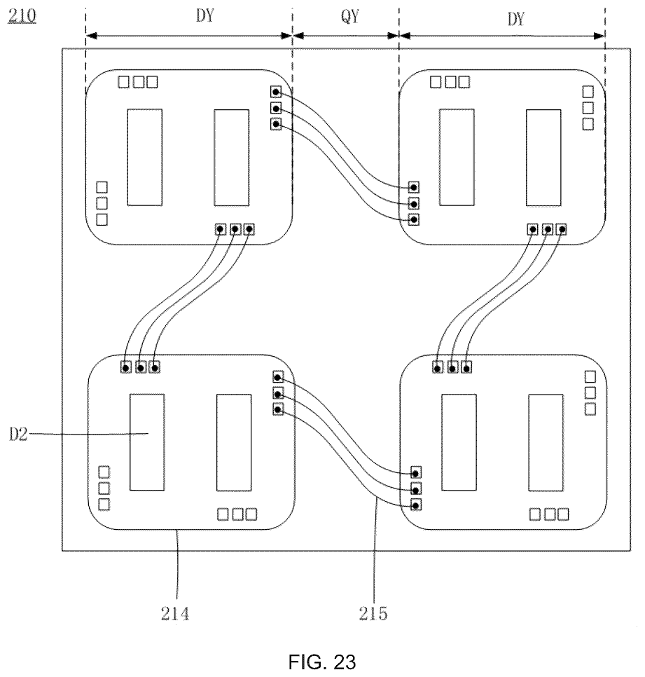

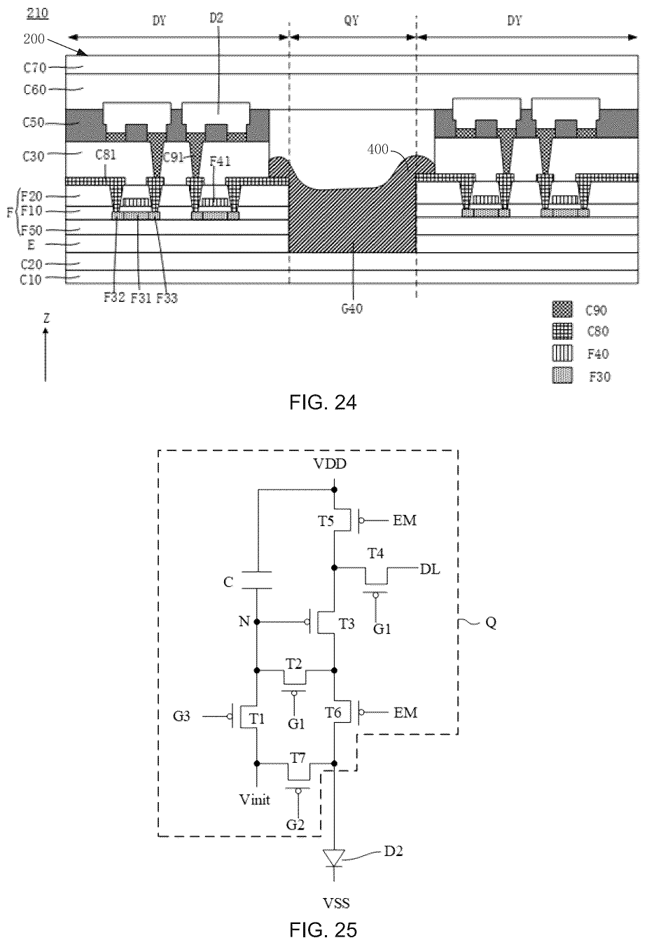

Referring to FIGS. 23 and 24, the first support layer is located on a side of the display structure 214 facing away from the display surface of the stretchable display panel 210; and the display surface is a surface of the stretchable display panel 210 for display images. For example, the display structure 214 is pasted on the first support layer. In this case, the first support layer may be understood as the first optical adhesive layer C20 and the first flexible protective film C10 that are stacked.

The first connection line G40 is connected to a portion of the display structure 214 proximate to the display surface. For example, the first connection line G40 is connected to a first connection portion C81 of the display structure 214 proximate to the display surface. In this case, the connection structure 215 may be understood as the first connection line G40. The material of the conductive pattern layer C80 may be a metal. The metal may be a single substance, such as titanium, aluminum, molybdenum, copper, silver, or gold; alternatively, the metal may be an alloy, such as alloys of the above single substances (e.g., titanium-aluminum alloy, or aluminum-neodymium alloy). For example, the material of the conductive pattern layer C80 and the material of the first connection line G40 may both be metals (e.g., titanium, aluminum, molybdenum, copper, silver, or gold).

The extensible portion is located on a surface of the first connection line G40 facing away from the first support layer G20 and in an area proximate to the display structure 214.

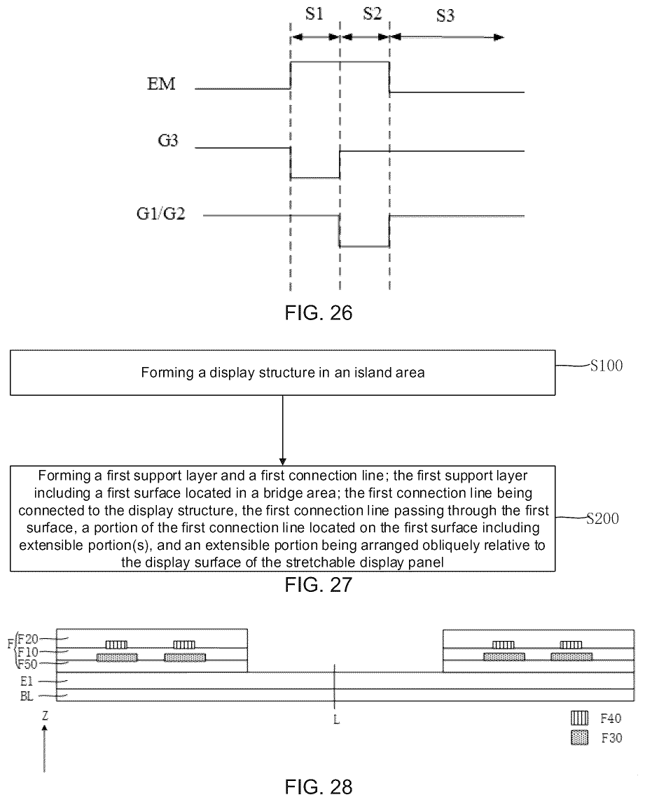

In some embodiments, referring to FIGS. 25 and 26, the stretchable display panel may include at least one (e.g., one or more) pixel circuit Q (which may also be referred to as a minimum repetition driving circuit). A pixel circuit Q is electrically connected to a light-emitting device D2, and is configured to provide an electrical signal with adjustable magnitude to the light-emitting device D2, so that the brightness of the light-emitting device D2 is adjustable.

In some embodiments, the pixel circuit Q may include a plurality of transistors and at least one (e.g., one or more) capacitors. For example, the pixel circuit Q may include two transistors and one capacitor to constitute a 2T1C structure. Alternatively, the pixel circuit Q may include more than two transistors and at least one capacitor to constitute a 3T1C structure (i.e., three transistors and one capacitor), a 4T1C structure (i.e., four transistors and one capacitor), a 5T1C structure (i.e., five transistors and one capacitor), a 7T1C structure (i.e., seven transistors and one capacitor), a 11T3C structure (i.e., eleven transistors and three capacitors), and the like. The pixel circuit Q of the 7T1C structure may make the brightness of the light-emitting devices D2 uniform. The pixel circuit Q with the 11T3C structure may eliminate the display uniformity of the light-emitting devices D2 at low gray levels.

Description is made by considering an example where the transistors in the embodiments of the present disclosure are thin film transistors but not limited to the thin film transistors, and the transistors may alternatively be field effect transistors.

The transistor includes a gate, a source, a drain, and an active pattern connected between the source and the drain. The active pattern of the transistor in the pixel circuit Q is, for example, the active pattern in the above active pattern layer. The material of the active pattern may include oxide semiconductor. For example, the oxide semiconductor may include one or combinations of indium gallium zinc oxide (IGZO), indium zinc tin oxide, indium gallium tin oxide (IGTO), indium zinc oxide (IZO) and C-axis aligned crystalline (CAAC). Correspondingly, the transistor may be an oxide transistor (which may also be referred to as an oxide thin film transistor). The material of the active pattern may alternatively include polysilicon (P-Si). Correspondingly, the transistor may be a polysilicon transistor. In a transistor, the active pattern may exhibit conductive properties under driven by voltages at the gate and the source, causing the source and the drain to be in an on state; or exhibit insulating properties, causing the source and the drain to be in an off state.

In some embodiments, all transistors in the pixel circuit Q are of the same type. For example, all are oxide transistors or all are polysilicon transistors. In some other embodiments, there are at least two types of transistors in the pixel circuit Q. For example, the pixel circuit Q may include some oxide transistors and some polysilicon transistors.

In some embodiments, all the transistors in the pixel circuit Q may be P-type transistors, it will be noted that, the embodiments of the present disclosure include, but are not limited thereto. For example, one or more transistors in the pixel circuit Q provided in the embodiments of the present disclosure may adopt N-type transistors, as long as that electrodes of the N-type transistors are correspondingly connected with reference to the electrodes of the corresponding P-type transistors in the embodiments of the present disclosure, and corresponding high voltages are applied to corresponding gates.

In the following, the pixel circuit Q is illustrated by considering an example of the 7T1C structure. Referring to FIG. 25, the pixel circuit Q of the 7T1C structure includes a first transistor T1, a second transistor T2, a third transistor T3, a fourth transistor T4, a fifth transistor T5, a sixth transistor T6, a seventh transistor T7 and a capacitor C. The embodiments of the present disclosure are illustrated by considering an example where the first transistor T1 to the seventh transistor T7 are all P-type transistors. The third transistor T3 may be a driving transistor. The gate of the third transistor T3 is coupled to a node N. Each transistor includes a gate, a first electrode and a second electrode. For a transistor, one of the first electrode and the second electrode is the source, and the other thereof is the drain. For example, the first electrode is the drain, and the second electrode is the source.

The gate of the third transistor T3 is coupled to the node N.

The gate of the first transistor T1 is coupled to a first reset signal terminal G3, the first electrode of the first transistor T1 is coupled to an initialization signal terminal Vinit, and the second electrode of the first transistor T1 is coupled to the node N.

The gate of the second transistor T2 is coupled to a gate line G1, the first electrode of the second transistor T2 is coupled to the second electrode of the third transistor T3, and the second electrode of the second transistor T2 is coupled to the node N. The gate of the transistor T4 is coupled to the gate line G1, the first electrode of the transistor T4 is coupled to a data line DL, and the second electrode of the transistor T4 is coupled to the first electrode of the third transistor T3.

The gate of the fifth transistor T5 is coupled to a light-emitting control signal terminal EM, the first electrode of the fifth transistor T5 is coupled to a first power supply voltage terminal VDD, and the second electrode of the fifth transistor T5 is coupled to the first electrode of the third transistor T3.

The gate of the sixth transistor T6 is coupled to the light-emitting control signal terminal EM, the first electrode of the sixth transistor T6 is coupled to the second electrode of the third transistor T3, and the second electrode of the sixth transistor T6 is coupled to a first electrode (such as an anode) of the light-emitting device D2. The second electrode (such as a cathode) of the light-emitting device D2 is coupled to a second power supply voltage terminal VSS.

The gate of the seventh transistor T7 is coupled to a second reset signal terminal G2, the first electrode of the seventh transistor T7 is coupled to the initialization signal terminal Vinit, and the second electrode of the seventh transistor T7 is coupled to the first electrode of the light-emitting device D2.

One end of the capacitor C is coupled to the node N, and the other end of the capacitor C is coupled to the first power supply voltage terminal VDD.

The voltage provided by the first power supply voltage terminal VDD may be greater than the voltage provided by the second power supply voltage terminal VSS, and may also be greater than the voltage provided by the initialization signal terminal Vinit. In addition, for example, the gate line G1, the first reset signal terminal G3, and the second reset signal terminal G2 may each provide their respective signals, that is, the signals provided by the three may be different. As another example, the first reset signal terminal G3 and the second reset signal terminal G2 may provide the same signal. In this case, the two may be coupled; and the signals provided by the two are different from the signal provided by the gate line G1. As another example, the second reset signal terminal G2 and the gate line G1 may provide the same signal. In this case, the two may be coupled; and the signals provided by the two are different from the signal provided by the first reset signal terminal G3.

An operating process of the above pixel circuit Q includes, for example, the following phases.

In the reset phase (phase S1): the first transistor T1 is turned on in response to the signal provided by the first reset signal terminal G3 to transmit the signal provided by the initialization signal terminal Vinit (e.g., may be called an initialization signal) to the node N, so as to reset the node N.

In the data writing phase (phase S2): both the second transistor T2 and the fourth transistor T4 may be turned on in response to the scan signal provided by the gate line G1 to write the data signal (e.g., marked as Vdate) provided by the data line DL to the node N, and start charging the capacitor C simultaneously. The voltage at the node N may be the compensated data signal, for example, Vdate+Vth, where Vth is the threshold voltage of the third transistor. The seventh transistor T7 is turned on in response to the signal provided by the second reset signal terminal G2 to transmit the initialization signal provided by the initialization signal terminal Vint to the first electrode of the light-emitting device D2, so as to reset the first electrode of the light-emitting device D2.

In the light-emitting phase (phase S3): both the fifth transistor T5 and the sixth transistor T6 may be turned on in response to the signal provided by the light-emitting control signal terminal EM, so that a path from the first power supply voltage terminal VDD to the second power supply voltage terminal VSS sequentially through the fifth transistor T5, the third the transistor T3, the sixth transistor T6, and the light-emitting device D2 is conductive, and thus the light-emitting device D2 can work (e.g., emit light).

For example, the transistors in the pixel circuit Q of the 7T1C structure may all be polysilicon transistors. As another example, the first transistor T1 and the second transistor T2 in the pixel circuit Q of the 7T1C structure may be oxide thin film transistors, so as to reduce the leakage current of the first transistor T1 and the second transistor T2, so that the voltage at the node N may be well maintained; and other transistors may be polysilicon transistors.

The embodiments of the present disclosure further provide a method for manufacturing a stretchable display panel. The stretchable display panel includes an island area and a bridge area that are connected. Referring to FIG. 27, the method includes steps S100 and S200.

In step S100, a display structure is formed in the island area.

In step S200, a first support layer and a first connection line are formed. The first support layer includes a first surface located in the bridge area. The first connection line is connected to the display structure. The first connection line passes through the first surface, a portion of the first connection line located on the first surface includes extensible portion(s), and the extensible portion is arranged obliquely relative to the display surface of the stretchable display panel.

For the description of the steps S100 and S200, reference may be made to the relevant description of the above stretchable display panel.

In some embodiments, forming the first support layer G20 and the first connection line G40 may include the following contents.

Referring to FIG. 28, a circuit layer F is provided. A hollow area L is formed in the circuit layer F. For example, the hollow area L is formed in the circuit layer F by exposure and development.

In some examples, before providing the circuit layer F, the method further includes: providing a substrate BL, the material of the substrate BL may be glass; forming an initial substrate E1 on the substrate BL; and forming the circuit layer F on the initial substrate E1. For the material of the circuit layer F in the method for manufacturing the stretchable display panel, reference may be made to the relevant description of the circuit layer F in the stretchable display panel.

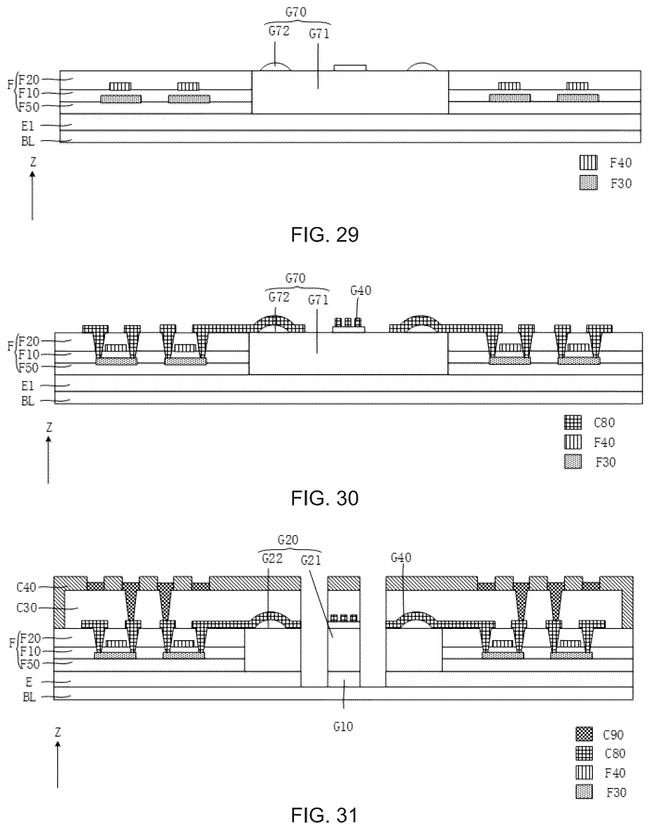

Referring to FIG. 29, a first initial support layer G70 is formed in the hollow area L. For the material of the first initial support layer G70 in the method for manufacturing the stretchable display panel, reference may be made to the relevant description of the first support layer G20 in the stretchable display panel. In some examples, the first initial support layer G70 may include a first flexible sub-layer G71 and a first flexible sub-portion G72 that are stacked.

Referring to FIG. 30, a first connection line G40 is formed on a surface of the first initial support layer G70 away from the initial substrate E1. For the description of the first connection line G40 in the method for manufacturing the stretchable display panel, reference may be made to the relevant description of the first connection line G40 in the stretchable display panel.

In some examples, forming the first connection line G40 on a surface of the first initial support layer G70 away from the initial substrate E1 includes: forming a conductive pattern layer C80. That is, the conductive pattern layer C80 and the first connection line G40 are formed by a single patterning process. For the description of the conductive pattern layer C80 in the method for manufacturing the stretchable display panel, reference may be made to the relevant description of the conductive pattern layer C80 in the stretchable display panel.

Referring to FIG. 31, part of the first initial support layer G70 is removed to form the first support layer G20. In some examples, part of the first flexible sub-layer G71 and the first flexible sub-portion G72 are removed to correspondingly form the first flexible layer G21 and the first flexible portion G22.

In some examples, removing part of the first initial support layer G70 to form the first support layer G20 includes: forming a shielding layer C40 on the first initial support layer G70; removing the part of the first initial support layer G70 by using the shielding layer C40 to form the first support layer G20. For example, a third insulating layer C30 is further formed between the first initial support layer G70 and the shielding layer C40, and part of the third insulating layer C30 is also removed by using the shielding layer C40. As another example, part of the initial substrate E1 is removed to form the first substrate G10 and the second substrate E. In this case, the first substrate G10 and the second substrate E are made of the same material. A lead layer C90 is formed on the shielding layer C40. The lead layer C90 includes a plurality of guide portions. For the description of the lead layer C90 in the method for manufacturing the stretchable display panel, reference may be made to the relevant description of the lead layer C90 in the stretchable display panel.

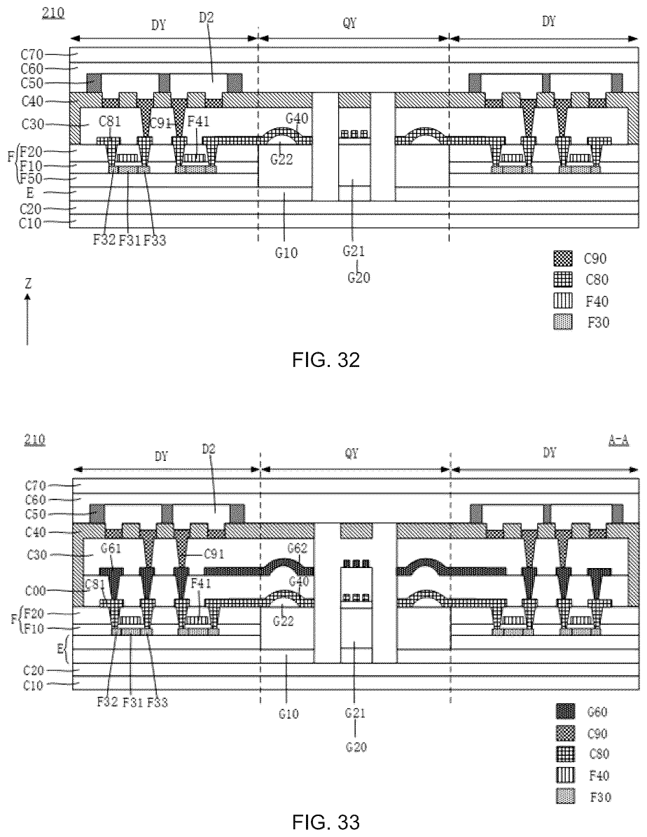

For example, referring to FIG. 32, after removing part of the first initial support layer G70 to form the first support layer G20, the method further includes the following contents.

The light-emitting device D2 is connected to the guide portion. A barrier adhesive C50 is provided at a periphery of the light-emitting device D2. The second flexible protective film C70 is pasted on a surface of the light-emitting device D2 away from the third insulating layer C30 by the second optical adhesive layer C60. The substrate BL is removed. The first flexible protective film C10 is pasted on the second substrate E of the display structure and the first substrate of the connection structure by the first optical adhesive layer C20.

For example, referring to FIG. 33, after forming the first connection line G40 on the surface of the first initial support layer G70 away from the initial substrate E1, and before removing part of the first initial support layer G70 to form the first support layer G20, the method further includes the following contents.

At least one first organic planarization layer C00 is formed, and the first organic planarization layer C00 and the first support layer G20 are stacked. A second connection line G62 is formed on a side of the first organic planarization layer C00 away from the first support layer G20, and the second connection line G62 is connected to the display structure. In some examples, a conductive layer G60 is formed on a side of the first organic planarization layer C00 away from the first support layer G20; and the second connection line G62 and the second connection portion G61 may be formed by a single patterning process. For example, part of the first organic planarization layer C00 is further removed by using the shielding layer C40.

The structure of the second support layer is the same or substantially the same as the structure of the first support layer G20, and the structure of the second connection line G62 is the same or substantially the same as the structure of the first connection line G40. The second support layer is a portion of the first organic planarization layer C00 located in the island area. The second connection line G62 is connected to the display structure and passes through the second support layer.

In some other embodiments, forming the first support layer G20 and the first connection line G40 may further include the following contents.

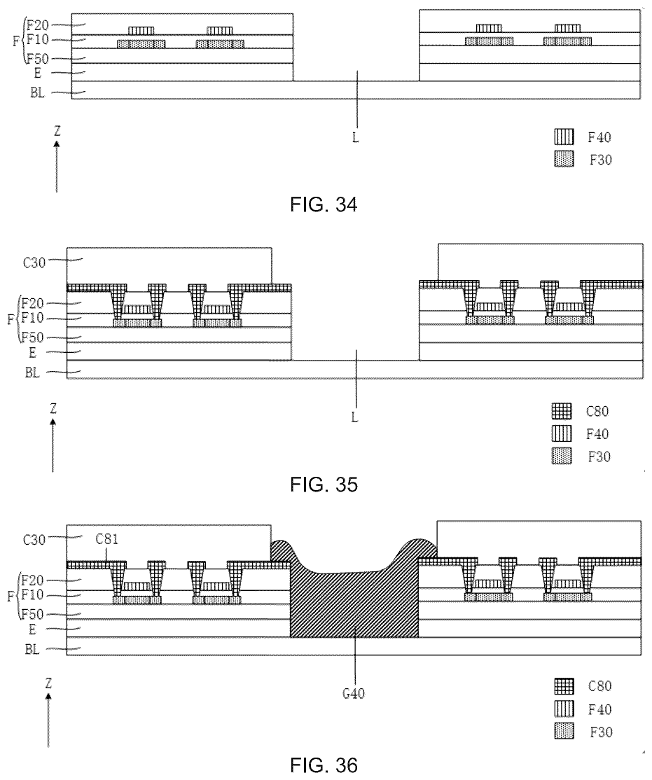

Referring to FIG. 34, a substrate BL is provided. The material of the substrate BL may be glass. An initial substrate E1 is formed on the substrate BL. A circuit layer F is formed on the initial substrate E1. For the description of the circuit layer F in the method for manufacturing the stretchable display panel, reference may be made to the relevant description of the circuit layer F in the stretchable display panel. A hollow area L is formed in the circuit layer F. The hollow area L is formed in the circuit layer F, for example, by exposure and development. Part of the initial substrate E1 is removed to form a second substrate E. For example, the second insulating layer (in this case, the second insulating layer may be understood as a mask to prevent the circuit layer F from being etched) in the circuit layer F is formed, by exposure and development, to etch part of the initial substrate E1 to form the second substrate E. The part of the initial substrate E1 may be understood as a portion of the initial substrate E1 directly opposite to the hollow area L. In the example, it can be understood that there is no first substrate.

Referring to FIG. 35, a conductive pattern layer C80 is formed on a side of the circuit layer F away from the substrate BL, and the conductive pattern layer C80 includes a plurality of first connection portions. A third insulating layer C30 is formed on a side of the conductive pattern layer C80 away from the substrate BL. The third insulating layer C30 has a gap, and the gap exposes a portion of the first connection portion. For example, the gap is formed in the third insulating layer C30 by exposure.

Referring to FIG. 36, a first connection line G40 is formed in the hollow area L, and the first connection line G40 is connected to a portion of the first connection portion. The portion of the first connection portion is the portion of the first connection portion exposed by the above gap. The first connection line G40 may be formed by inkjet printing, 3D printing, printing, nanoimprinting, or other processes.

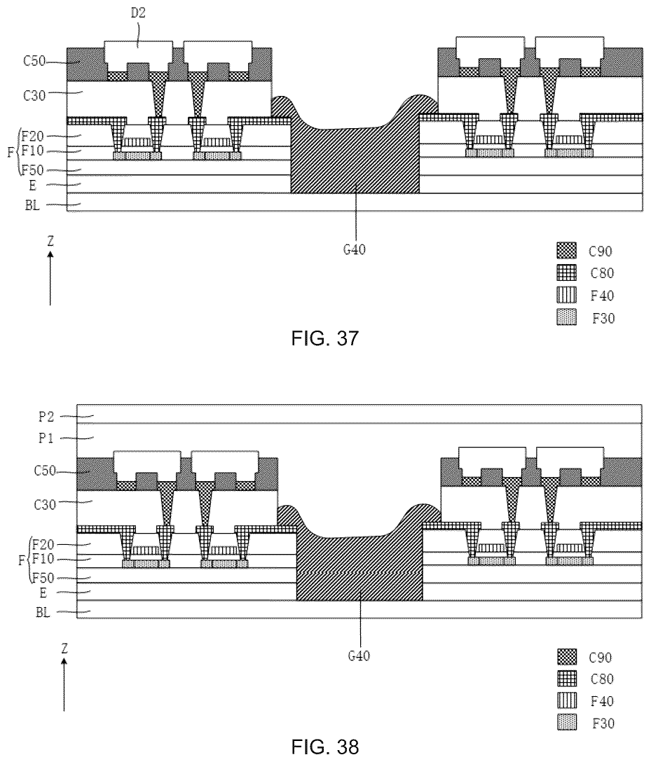

Referring to FIG. 37, a lead layer C90 is formed on a side of the third insulating layer C30 away from the substrate BL; and the lead layer C90 includes a plurality of guide portions. For the description of the lead layer C90 in the method for manufacturing the stretchable display panel, reference may be made to the relevant description of the lead layer C90 in the stretchable display panel. The light-emitting device D2 is connected to the guide portion. A barrier adhesive C50 is provided at a periphery of the light-emitting device D2.

Referring to FIG. 38, a third flexible protective film P2 is pasted on a side of the first connection line G40 away from the circuit layer F by a third optical adhesive layer P1. A portion of the third optical adhesive layer P1 is located in the hollow area L and is in contact with the first connection line G40. In this way, the third flexible protective film P2 and third optical adhesive layer P1 provided may maintain good integrity of the stretchable display panel, thereby facilitating the removal of the substrate BL. The material of the third flexible protective film P2 may refer to the relevant description of the material of the first flexible protective film. The adhesion force of the third optical adhesive layer P1 is smaller than the adhesion force of the second optical adhesive layer C60, which facilitates the separation of the third optical adhesive layer P1 from the display structure and the first connection line G40.

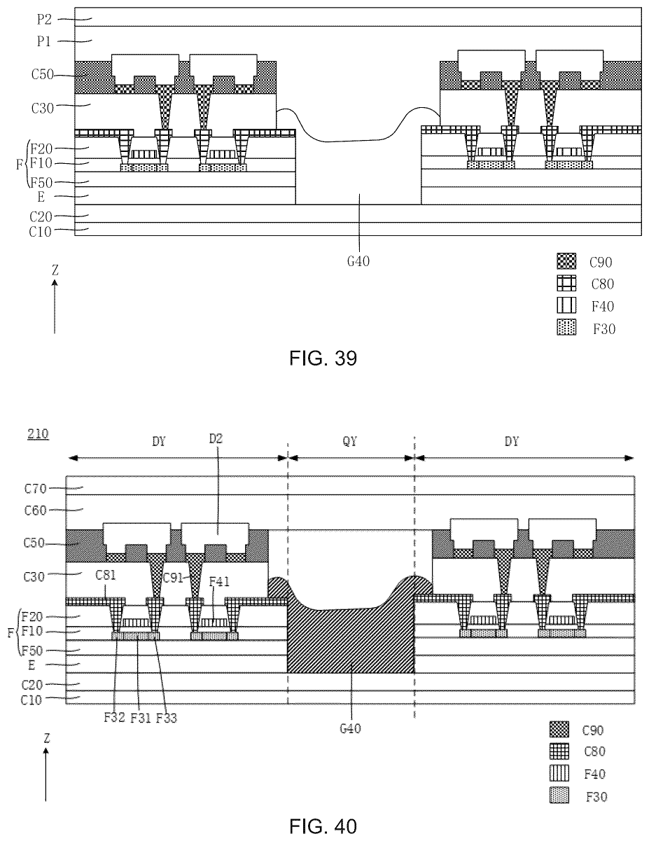

Referring to FIG. 39, the substrate BL is removed. For example, the substrate BL is peeled off using laser lift-off technology. The first flexible protective film C10 is pasted on the second substrate E of the display structure by the first optical adhesive layer C20. Referring to FIG. 40, the third flexible protective film P2 and the third optical adhesive layer P1 are removed. For example, the third flexible protective film P2 and the third optical adhesive layer P1 are peeled off using laser lift-off technology. The second flexible protective film C70 is pasted on a side of the light-emitting device D2 away from the third insulating layer C30 by the second optical adhesive layer C60.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A stretchable display panel, having an island area and a bridge area that are connected; the stretchable display panel comprising:
a display structure located in the island area;
a first support layer including a first surface located in the bridge are; and
a first connection line; wherein the first connection line is connected to the display structure, the first connection line passes through the first surface, a portion of the first connection line located on the first surface includes least one extensible portion, and an extensible portion is disposed obliquely relative to a display surface of the stretchable display panel.

2. The stretchable display panel according to claim 1, wherein
the first support layer is of a flexible structure; the first surface includes a first planarization portion and a first deformation portion, the first planarization portion is parallel to the display surface, the first deformation portion is convex or concave relative to the first planarization portion in a first direction, and the first direction is perpendicular to the display surface; the first connection line passes through the first planarization portion and the first deformation portion, and the extensible portion covers the first deformation portion.

3. The stretchable display panel according to claim 2, wherein
the first support layer includes a first flexible layer and a first flexible portion; the first flexible portion is located on a surface of the first flexible layer proximate to the display surface of the stretchable display panel; and the first deformation portion includes at least part of a surface of the first flexible portion proximate to the display surface.

4. The stretchable display panel according to claim 3, wherein
a shape of a cross section of the first flexible portion includes any one of a trapezoid, an arch and a rectangle, and the cross section is a surface taken along the first direction and parallel to an extension direction of the first connection line.

5. The stretchable display panel according to claim 3, wherein
the first support layer further includes a second flexible portion; the second flexible portion is located on a surface of the first flexible portion facing away from the first flexible layer, and an orthographic projection of the second flexible portion on the first flexible layer is located within an orthographic projection of the first flexible portion on the first flexible layer; and
the first deformation portion includes a surface of an entirety of the first flexible portion and the second flexible portion proximate to the display surface.

6. The stretchable display panel according to claim 5, wherein
a shape of a cross section of the second flexible portion includes any one of a trapezoid, an arch and a rectangle, and the cross section is a surface taken along the first direction and parallel to the extension direction of the first connection line.

7. The stretchable display panel according to claim 2, further comprising at least one first organic planarization layer and at least one second connection line; wherein
the first organic planarization layer and the first support layer are stacked; a portion of the first organic planarization layer located in the bridge area is a second support layer; a structure of the second support layer is same or substantially same as a structure of the first support layer, and a structure of the second connection line is same or substantially same as a structure of the first connection line; the second connection line is connected to the display structure and passes through the second support layer.

8. The stretchable display panel according to claim 7, wherein
a dimension of the first organic planarization layer in the first direction is less than or equal to 2 nm.

9. The stretchable display panel according to claim 1, wherein
the at least one extensible portion includes a plurality of extensible portions, and the plurality of extensible portions are sequentially arranged in an extension direction of the first connection line.

10. The stretchable display panel according to claim 1, wherein
a shape of a cross section of the extensible portion includes any one of a trapezoid, an arch and a rectangle, the cross section is a surface taken along a first direction and parallel to an extension direction of the first connection line, and the first direction is perpendicular to the display surface.

11. The stretchable display panel according to claim 1, wherein
the first support layer is located on a side of the display structure facing away from the display surface of the stretchable display panel; the first connection line is connected to a portion of the display structure proximate to the display surface; and
the extensible portion is located in a surface of the first connection line facing away from the first support layer.

12. A method for manufacturing a stretchable display panel, the stretchable display panel including an island area and a bridge area that are connected; the method comprising:
forming a display structure in the island area; and
forming a first support layer and a first connection line; wherein the first support layer includes a first surface located in the bridge area; the first connection line is connected to the display structure, the first connection line passes through the first surface, a portion of the first connection line located on the first surface includes at least one extensible portion, and an extensible portion is disposed obliquely relative to a display surface of the stretchable display panel.

13. The method according to claim 12, wherein forming the first support layer and the first connection line includes:
providing a first initial support layer;
forming the first connection line on the first initial support layer; and
removing part of the first initial support layer to form the first support layer.

14. The method according to claim 13, wherein after forming the first connection line on the first initial support layer and before removing the part of the first initial support layer to form the first support layer, the method further comprises:
forming at least one first organic planarization layer, the first organic planarization layer and the first support layer being stacked; and
forming a second connection line on a side of the first organic planarization layer away from the first support layer, the second connection line being connected to the display structure.

15. A display apparatus, comprising:
the stretchable display panel according to claim 1.

16. The stretchable display panel according to claim 2, wherein
the first support layer has a single-layer structure and includes a first flexible layer; a surface of the first flexible layer proximate to the display surface of the stretchable display panel includes a first recessed portion, and the first deformation portion is the first recessed portion.

17. The stretchable display panel according to claim 16, wherein
a shape of a cross section of the first recessed portion includes one of a trapezoid, an arch and a rectangle, and the cross section is a surface taken along the first direction and parallel to an extension direction of the first connection line.

18. The stretchable display panel according to claim 7, wherein
the first connection line and the second connection line are connected in parallel.

19. The stretchable display panel according to claim 1, wherein
the at least one extensible portion includes a protrusion and/or a depression in a first direction, and the first direction is perpendicular to the display surface.

20. The stretchable display panel according to claim 1, further comprising a conductive pattern layer, wherein a material of the conductive pattern layer is same as a material of the first connection line.
